(19) United States
(12) Patent Application Publication
(10) Pub. No.: US 2026/0367139 A1
(43) Pub. Date: Nov. 19, 2026

(54) WAFER MULTI-TEST SYSTEM INCLUDING CONTACT DEVICE

(71) Applicant: UNITEST INC., Gyeonggi-do (KR)

(72) Inventor: Ho Suck Jung, Gyeonggi-do (KR)

(73) Assignee: UNITEST INC., Gyeonggi-do (KR)

(21) Appl. No.: 19/229,211

(22) Filed: Jun. 5, 2025

(30) Foreign Application Priority Data
May 13, 2025 (KR) 1020250062010

(51) Int. Cl. G01R 31/28; G01R 1/04

(52) U.S. Cl. CPC G01R 31/2831; G01R 1/0491

(57) ABSTRACT

Disclosed is a wafer multi-test system including a contact device that serves as an interface for multi-testing of wafers, the wafer multi-test system including: a contact device provided with a mount that is movable in an upward direction or a downward direction, and has a lower surface on which a first ZIF connector electrically connectable to a cartridge in which a wafer is seated when moving in the downward direction is disposed, in which the contact device includes a cable system that is configured to transmit an electrical signal of a tester to the cartridge to inspect whether the wafer is good or defective when the contact device is electrically connected to the cartridge.

### CROSS-REFERENCE TO RELATED APPLICATIONS

This application claims priority to and the benefit of Korean Patent Application No. 10-2025-0062010 filed in the Korean Intellectual Property Office on May 13, 2025, the entire contents of which are incorporated herein by reference.

### TECHNICAL FIELD

The present invention relates to a wafer multi-test system including a contact device, and more specifically, to a wafer multi-test system including a contact device that may reduce unnecessary packaging costs by inspecting a defective product through multi-testing of wafers before semiconductor packaging.

### BACKGROUND ART

In general, semiconductor devices, such as integrated circuit devices of semiconductor devices, may be formed by repeatedly performing a series of treatment processes on a wafer. For example, semiconductor devices may be formed on a wafer by repeatedly performing a deposition process to form a film on a wafer, an etching process to form patterns having electrical properties on the wafer on which the deposition has been performed, an ion implantation or diffusion process to inject or diffuse impurities into the patterns, a cleaning and rinsing process to remove impurities from the patterned wafer, and the like.

After the semiconductor devices which have been conducted a series of processes are formed, an electrical inspection process may be performed to inspect electrical properties of the semiconductor devices. The inspection process is performed by a probe station containing a probe card having multiple probes and a tester connected to the probe card to provide an electrical signal.

In general, a probe station includes an inspection chamber, a chuck placed in the inspection chamber to support a wafer, a chuck transfer device to drive the chuck, a probe card having a plurality of probes configured to contact semiconductor devices formed on the wafer, and a tester connected to the probe card to perform a test.

On the other hand, the test system of a semiconductor package that is the complete form of a wafer loads the semiconductors into a socket so that semiconductors are tested in turn and sorts the semiconductors into good products and graded products according to the results of the test. In general, semiconductors that are mass-produced, such as memories, are thoroughly tested, so reducing the test time to detect defects plays an important role in reducing the overall production cost. Therefore, the package-stage test performs a large amount of multi-site tests, which refers to a technology that reduces the overall test cost by testing multiple devices at the same time in one Automated Test Device (ATE). For example, in the case of high-speed memory tests currently on the market, 1,024 memories may be tested simultaneously based on DDR 3, and the operating speed of the Automatic Test Device (ATE) reaches 2.4Gbps. When the number of channels (pins) required to test one device is N, the multisite test may be said to be effective only when the number of channels required to test m devices tested at the same time is less than m*N.

However, in order to increase the number of devices that can be tested at the same time, the semiconductor package test currently on the market utilizes a BOST structure which implements related functions on the interface board located between the ATE and the semiconductor package (DUT) considerably. An ATE or an Algorithmic Pattern Generator (ALPG) that generates a pattern based on a signal transmitted from the ATE becomes a test source, and the interface board having the BOST function applies a test pattern to the semiconductor package (DUT). In this case, until now, a bus structure has been commonly utilized to use a data connection structure, that is, an interconnect structure, to apply patterns to the multiple semiconductor packages (DUTs) at the same time. The bus structure has the advantage of being easy to design and short transmission time, but the number of modules that can be connected to the bus is limited, and the operation of the bus controller becomes complicated, such as prioritizing the use of the bus, in proportion to the number of connected modules.

The present invention develops a wafer multi-test system with a tact device that is capable of reducing unnecessary packaging costs by inspecting a defective product through multi-testing of wafers before semiconductor packaging, before detecting a defective products in a test system of a semiconductor package that is a related art.

### Prior Art Literature

### Patent Document

(Patent Document 1) Korean Patent Application Publication No. 10-2014-0112135 (published on September 23, 2014)

### SUMMARY OF THE INVENTION

The present invention has been made in an effort to solve the foregoing problems, and provide a wafer multi-test system including a contact device that may reduce unnecessary packaging costs by inspecting a defective product through multi-testing of wafers before semiconductor packaging.

The present invention has also been made in an effort to solve the foregoing problems, and provide a wafer multi-test system including a contact device that is capable of performing multi-testing of wafers without interference of a signal from another tester by allowing a tester in charge of each slot to verify only performance of a wafer seated in a cartridge in a slot after placing the cartridge in which the wafer is seated in each slot in a chamber.

However, the technical problems to be achieved in the present invention are not limited to the technical problems mentioned above, and other technical problems not mentioned may be clearly understood by those of ordinary skill in the art to which the present invention belongs from the following description.

An exemplary embodiment of the present invention provides a wafer multi-test system including a contact device, the wafer multi-test system including: a contact device provided with a mount that is movable in an upward direction or a downward direction, and has a lower surface on which a first ZIF connector electrically connectable to a cartridge in which a wafer is seated when moving in the downward direction is disposed, in which the contact device includes a cable system that is configured to transmit an electrical signal of a tester to the cartridge to inspect whether the wafer is good or defective when the contact device is electrically connected to the cartridge.

Further, the contact device may include a plurality of vertical drive units arranged at respective corners of the mount to move the mount in the upward direction or the downward direction or fix a position of the mount.

Further, the plurality of vertical drive units may move the mount in the upward direction or the downward direction according to an applied pneumatic signal, but fix the position of the mount when the supplied pneumatic pressure is cut off.

Further, in the contact device, the first ZIF connector may be disposed in a circular shape in a center of the mount.

Further, the first ZIF connector may be electrically connected to a second ZIF connector disposed in a circular shape on a circumference of an interface board provided in the cartridge when the mount moves in the downward direction.

Further, the contact device may include a plurality of lock/unlock actuators disposed on respective sides of the mount and connected to the first ZIF connector to drive a latch of the first ZIF connector in a locked or unlocked state.

Further, the plurality of lock/unlock actuators may drive the latch of the first ZIF connector in the locked state according to an applied pneumatic signal to allow the first and second ZIF connectors to be electrically connected when the contact device moves in the downward direction, and when the supplied pneumatic pressure is cut off after a test of the wafer is completed, the plurality of lock/unlock actuators may drive the locked-state latch of the first ZIF connector in the unlocked state to release the electrical connection between the first and second ZIF connectors.

Further, the contact device may include a guide pin placed at a position where the first ZIF connector is divided into a plurality of connectors to correct vertical and horizontal position alignment errors of the first ZIF connector when the contact device and the cartridge are electrically connected.

Further, the cartridges may be provided in plural to be disposed in a plurality of slots formed in a chamber accommodating the contact device, the cartridge, and the tester, respectively, and the testers may be provided in plural to inspect only whether the wafer seated in the cartridge of each slot is good or defective.

Further, the cable system may allow the electrical signal to be transmitted to the cartridge in the slot in which each tester is charge to proceed multi-testing of the wafers.

Further, the contact device may be configured to transmit an electrical signal output from each tester to the cartridge in the slot without interference of an electrical signal from another tester through an independent signal path, to improve test reliability and efficiency during the multi-testing of the wafers.

The present invention may reduce unnecessary packaging costs by inspecting a defective product through multi-testing of wafers before semiconductor packaging.

Further, the present invention may perform multi-testing of wafers without interference of a signal from another tester by allowing a tester in charge of each slot to verify only performance of a wafer seated in a cartridge in a slot after placing the cartridge in which the wafer is seated in each slot in a chamber.

On the other hand, the effects that may be obtained from the present invention are not limited to the effects mentioned above, and other effects not mentioned may be clearly understood by those of ordinary skill in the art to which the present invention belongs from the description below.

### BRIEF DESCRIPTION OF THE DRAWINGS

FIG. 1 is a block diagram of a wafer multi-test system including a contact device according to an exemplary embodiment of the present invention.

FIG. 2 is a use state diagram of the wafer multi-test system including the contact device according to the exemplary embodiment of the present invention.

FIGS. 3A to 3D are block diagrams of the contact device according to the exemplary embodiment of the present invention.

FIGS. 4A to 4C are block diagrams of the cartridge according to the exemplary embodiment of this invention.

FIGS. 5 to 8 are diagrams illustrating a procedure of an electrical connection between the contact device and the cartridge according to the exemplary embodiment of the present invention.

### DETAILED DESCRIPTION

Hereinafter, an exemplary embodiment of the present invention will be described with reference to accompanying drawings so as to be easily implement the present invention by a person ordinary skilled in the art. However, since the description of the present invention is only an exemplary embodiment for structural or functional explanation, the scope of the present invention should not be interpreted as being limited by the exemplary embodiment described in the text. That is, since the exemplary embodiment may be changed in various ways and may have various forms, the scope of the present invention should be understood as including equivalents capable of realizing the technical idea. In addition, the purpose or effect presented in the present invention does not mean that a specific exemplary embodiment should include all of the purposes or effects or only include such effects, so the scope of the present invention should not be understood as limited thereto.

The meaning of the terms described in the present invention should be understood as follows.

Terms, such as “first” and “second”, are intended to distinguish one component from another component, and the scope of rights should not be limited by these terms. For example, a first component may be named as a second component, and similarly, a second component may be named as a first component. When it is mentioned that a component is “connected” to another component, it should be understood that a component may be directly connected to another component, but another component may be interposed therebetween. On the other hand, when it is mentioned that one component is “directly connected” to another component, it should be understood that no other component exists therebetween. On the other hand, other expressions that describe the relationship between the components, such as “between” and “just between” or “adjacent to” and “directly adjacent to”, should be interpreted in a similar manner.

Singular expressions used herein include plurals expressions unless they have definitely opposite meanings in the context. In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Unless otherwise defined, all terms used herein have the same meaning as those generally understood by those of ordinary skill in the field to which the present invention belongs. Terms generally defined in dictionaries should be interpreted as consistent with the contextual meaning of related technologies, and may not be interpreted as having an ideal or excessively formal meaning unless explicitly defined in the present invention.

### Configuration of Wafer Multi-test System

Hereinafter, a wafer multi-test system 100 including a contact device according to an exemplary embodiment of the present invention will be described in detail with reference to the accompanying drawings.

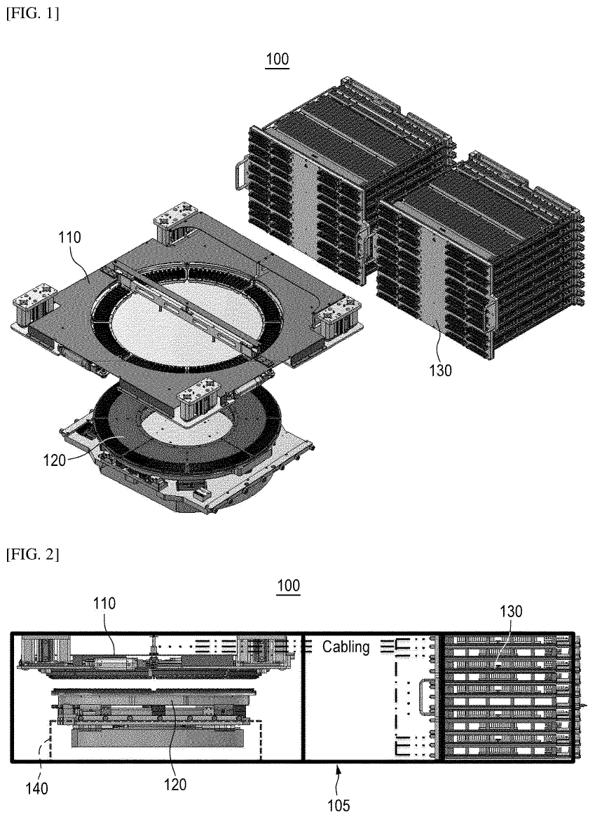

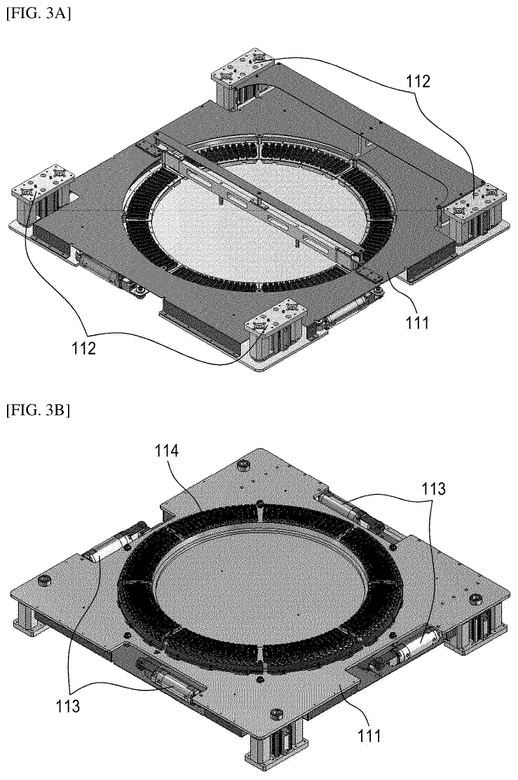

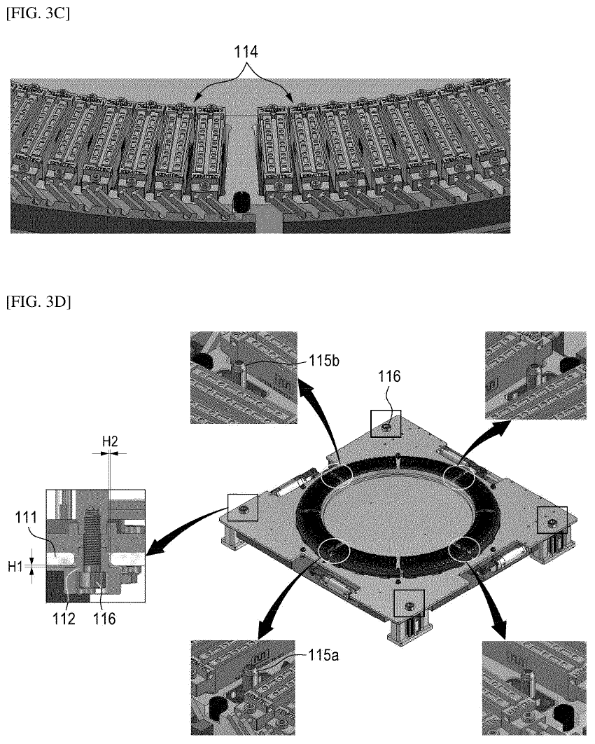

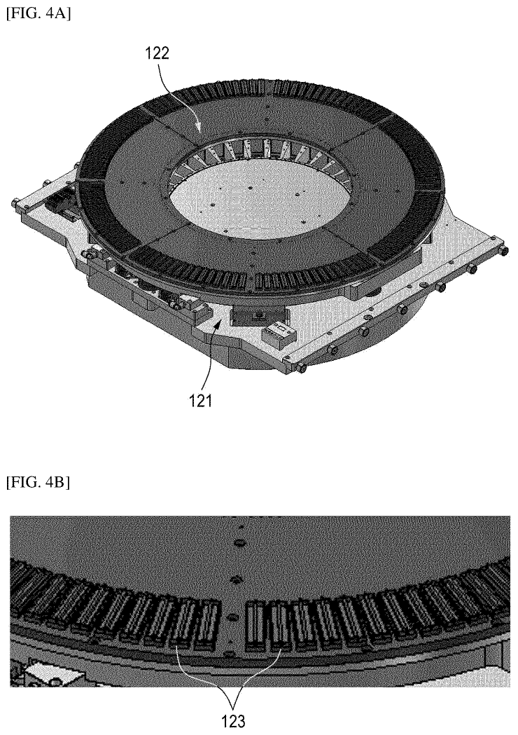

FIG. 1 is a block diagram of a wafer multi-test system including a contact device according to an exemplary embodiment of the present invention, FIG. 2 is a use state diagram of the wafer multi-test system including the contact device according to the exemplary embodiment of the present invention, FIG. 3 is a block diagram of the contact device according to the exemplary embodiment of the present invention, and FIG. 4 is a block diagram of the cartridge according to the exemplary embodiment of this invention.

Referring to FIGS. 1 to 4, the wafer multi-test system 100 including the contact device according to the exemplary embodiment of the present invention is a system equipped including a contact device 110 that serves as an interface for multi-test (or parallel test) of a wafer (not illustrated), and includes a cartridge 120, a tester 130, and a table part 140 for testing a wafer, as well as the contact device 110.

Furthermore, as illustrated in FIG. 2, the wafer multi-test system 100 may be implemented as a single module because the contact device 110, the cartridge 120, the tester 130, and the table part 140 may be modularized through a chamber 105.

In the exemplary embodiment, although not illustrated in the drawing, the chamber 105 may have a plurality of slots in which one or more cartridges 120 may be disposed in an interior space for multi-testing of the wafers (not illustrated).

The contact device 110 of the present invention is a device serving as an interface for multi-testing wafers (not illustrated), and may be electrically connected to the cartridge 120 in which the wafer (not illustrated) is seated.

Referring to FIGS. 3A to 3D, the contact device 110 includes a mount 111, a vertical drive unit 112, a lock/unlock actuator 113, a first ZIF connector 114, a guide pin 115, and a bolt 116.

In the exemplary embodiment, the mount 111 may move in an upward direction or a downward direction by the vertical drive unit 112 provided on one side, or a position (or height) of the mount 111 may be fixed.

In addition, the mount 111 may be provided with the lock/unlock actuator 113 for driving a latch of the first ZIF connector 114 in a locked or unlocked state on the other side.

In addition, the mount 111 may have the first ZIF connector 114 that may be electrically connected to the cartridge 120 disposed on a lower surface thereof.

Additionally, the mount 111 does not limit its shape, but in one exemplary embodiment, the mount 111 may be implemented in the form of a polygon (e.g., a square) having four sides.

In the exemplary embodiment, the vertical drive unit 112 may be provided on one side of the mount 111, and preferably may be disposed at each corner of the mount 111.

That is, the number of vertical drive units 112 provided in the contact device 110 may vary depending on the shape of the mount 111, and in the exemplary embodiment, a plurality (preferably, four) may be disposed at the respective corners of the mount 111.

In addition, each of the vertical drive units 112 may be fixed in position while being disposed at each corner of the mount 111 through the bolt 116.

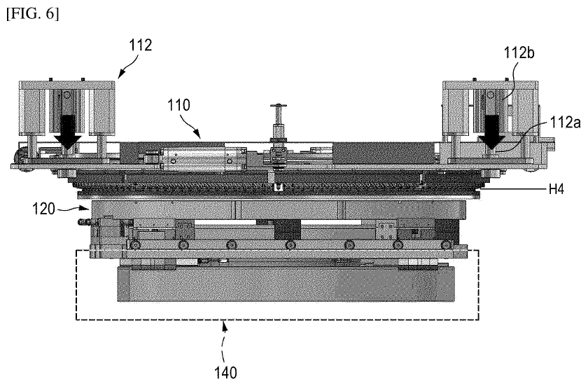

Further, each vertical drive unit 112 includes a shaft 112a and a pneumatic drive unit 112b as illustrated in FIG. 6, which will be described later, to move the mount 111 in the upward direction or the downward direction, or to fix the position of the mount 111.

In the exemplary embodiment, the shaft 112a may maintain a connection state with the mount 111 by the bolt 116, and moves in the upward direction or the downward direction or is fixed in position within the pneumatic drive unit 112b, thereby moving the mount 111 in the upward direction or the downward direction or fix the position of the mount 111.

In the exemplary embodiment, the pneumatic drive unit 112b moves the shaft 112a in the upward direction or the downward direction according to the applied pneumatic signal, and when the pneumatic pressure supplied to the pneumatic drive unit 112b is blocked, the shaft 112a may be blocked from moving in the upward direction or the downward direction and fixed in position.

Since it is possible to move the mount 111 in the downward direction for contact between the contact device 110 and the cartridge 120, the vertical drive unit 112 of the exemplary embodiment may mechanically maintain an electrical connection between the contact device 110 and the cartridge 120.

In the exemplary embodiment, the lock/unlock actuator 113 may be provided on the other side of the mount 111, preferably disposed on each side of the mount 111.

That is, the number of lock/unlock actuators 113 provided in the contact device 110 may vary depending on the shape of the mount 111, and in the exemplary embodiment, a plurality (preferably, four) of lock/unlock actuators 113 may be disposed on the respective sides of the mount 111.

Additionally, each lock/unlock actuator 113 may drive the latch of the first ZIF connector 114 in a locked state according to the applied pneumatic signal when the mount 111 moves in the downward direction, i.e., the contact device 110 moves in the downward direction, by the vertical drive unit 112.

In addition, each lock/unlock actuator 113 may drive the latch of the first ZIF connector 114 in the locked state to an unlocked state when the supplied pneumatic pressure is cut off.

The lock/unlock actuator 113 according to the exemplary embodiment may mechanically maintain an electrical connection between the contact device 110 and the cartridge 120 as it is possible to drive the latch of the first ZIF connector 114 in the locked state.

In the exemplary embodiment, the first ZIF connector 114 is a component capable of being electrically connected to a second ZIF connector 123 of the cartridge 120 in which the wafer (not illustrated) is seated, and may be disposed in a circular shape in the center of the mount 111.

Furthermore, when the contact device 110 and the cartridge 120 are electrically connected, the first ZIF connector 114 may transmit an electrical signal of the tester 130 to the cartridge 120 to inspect good products and defective products of the wafer (not illustrated).

In the exemplary embodiment, the guide pin 115 may correct a vertical and horizontal position alignment error of the first ZIF connector 114 when the contact device 110 and the cartridge 120 are electrically connected.

Additionally, the guide pin 115 may be placed in a position that divides the first ZIF connector 114 into multiple connectors to correct the vertical and horizontal position alignment error of the first ZIF connector 114.

Here, the correction of the vertical and horizontal position alignment error of the first ZIF connector 114 by the guide pin 115 means limiting the degree to which the latch of the first ZIF connector 114 rotates according to the pneumatic signal applied to the lock/unlock actuator 113 while in the unlocked state.

In addition, a plurality of guide pins 115 may be provided to be inserted into a plurality of first holes formed in the mount 111, respectively, to correspond to the position where the first ZIF connector 114 is divided into a plurality of connectors.

In addition, the plurality of guide pins 115 may protrude from the first hole to be in contact with the first ZIF connector 114 and inserted into the plurality of second holes (not illustrated) formed in the cartridge 120 to limit the degree to which the latch of the first ZIF connector 114 rotates.

The plurality of guide pins 115 include a first guide pin 115a serving as a reference point for forcing the degree to which the latch of the first ZIF connector 114 rotates, and a plurality of second guide pins 115b serving as an auxiliary point (preferably three).

In the exemplary embodiment, the first guide pin 115a may have a first diameter (e.g., Ø7), a plurality of second guide pins 115b may have a second diameter (e.g., Ø6) different from the first diameter, and the first diameter is preferably larger than the second diameter.

As such, the asymmetric design of the first guide pin 115a and the second guide pin 115b may prevent the second guide pin 115b from being assembled to the mount 111 through the first hole into which the first guide pin 115a is inserted, and conversely, prevent the first guide pin 115a from being assembled to the mount 111 through the first hole into which the second guide pin 115b is inserted.

In addition, the diameters of the first guide pin 115a and the plurality of second guide pins 115b are not limited to the first diameter and the second diameter of the exemplary embodiment, and the first diameter may be smaller than the second diameter, contrary to the exemplary embodiment.

Additionally, the first and second guide pins 115a and 115b are inserted into the plurality of second holes (not illustrated) formed in the cartridge 120, respectively, when the mount 111 moves in the downward direction in order to electrically connect the contact device 110 and the cartridge 120, allowing the contact device 110 and the cartridge 120 to remain parallel in the X, Y, and Z axes and simultaneously limiting the degree to which the latch of the first ZIF connector 114 rotates.

In one exemplary embodiment, the bolt 116 is coupled to the shaft 112a to maintain a state in which the plurality of vertical drive units 112 is disposed at the respective corners of the mount 111.

That is, the number of bolts 116 provided in the contact device 110 may vary depending on the number of vertical drive units 112, and in the exemplary embodiment, a plurality (preferably four) of bolts 116 may be provided in the contact device 110 to correspond to the number of vertical drive units 112 to fix the position of each vertical drive unit 112.

Additionally, the bolt 116 may adjust the position alignment error to ±1 mm based on the X, Y, and Z axes to correct the fine errors that occur during the electrical connection between the contact device 110 and the cartridge 120.

In addition, the bolt 116 accurately maintains a first gap H1 and a second gap H2 between the mount 111 and the vertical drive unit 112 to enable the vertical drive unit 112 to be clamped, and the first and second gaps H1 and H2 are not limited, but in the exemplary embodiment, the first and second gaps H1 and H2 may be a gap within a precise range of less than 1 mm.

Referring to FIGS. 4A to 4C, the cartridge 120 may include an interface board 122 and the second ZIF connector 123 on an upper portion 121 side in the exemplary embodiment, and a probe card (not illustrated), a wafer chuck (not illustrated), and a wafer (not illustrated) may be provided in an interior space formed through the upper portion 121 and a lower portion 124.

In this case, the upper portion 121 of the cartridge 120 refers to the upper surface facing the lower surface of the contact device 110 from which the first ZIF connector 114 protrudes when the contact device 110 and the cartridge 120 are electrically connected, and the lower portion 124 of the cartridge 120 refers to the lower surface connected to or coupled to the table part 140 for aligning the position of the cartridge 120 and inducing contact including the contact device 110.

In addition, the probe card (not illustrated) may apply an electric signal of the tester 130 to the wafer (not illustrated) seated in the wafer chuck (not illustrated), measure a response signal of the wafer (not illustrated), and transmit the response signal of the wafer (not illustrated) measured to the tester 130 in connection with the cable system.

Further, the wafer chuck (not illustrated) may fix a wafer (not illustrated) which is an experimental target of the tester 130.

In the exemplary embodiment, the second ZIF connector 123 may be electrically connected to the first ZIF connector 114 protruding from the lower surface of the mount 110 when the mount 110 moves in the downward direction.

To this end, the second ZIF connector 123 may be provided in a circumference portion of the circular interface board 122 facing the first ZIF connector 114 when the mount 110 moves in the downward direction.

In addition, the second ZIF connector 123 may be divided into a plurality of connectors by the second hole (not illustrated) for inserting the guide pins 115a and 115b.

Additionally, it is preferable that the second hole (not illustrated) is parallel to the first hole of the contact device 110 in the X, Y, and Z axes so that the guide pins 115a and 115b can be inserted when the cartridge 120 is parallel to the contact device 110 in the X, Y, and Z axes so as for the cartridge 120 to be electrically connected to the contact device 110.

In addition, it is preferable that the cartridge 120 is electrically connected to the contact device 110 by dividing the second ZIF connector 123 into the same shape as the first ZIF connector 114 based on the time when the cartridge 120 is parallel to the contact device 110 in the X, Y, and Z axes.

One or more cartridges 120 may be disposed in the slots formed in the interior space of the chamber 105 for multi-testing of the wafers (not illustrated).

In the exemplary embodiment, the tester 130 may transmit an electrical signal to the cartridge 120 to inspect good products and defective products of a wafer (not illustrated) seated in the cartridge 120, and may receive a response signal of the wafer (not illustrated) measured from the cartridge 120 to determine whether the wafer (not illustrated) is good or defective.

In addition, a plurality of testers 130 may be provided to inspect whether the wafer (not illustrated) seated in the cartridge 120 of each slot is good or defective, and the plurality of testers 130 may implement a multi-test of wafers (not illustrated) by inspecting whether the wafer (not illustrated) seated in the cartridge 120 of each slot is good or defective.

In addition, the tester 130 may be directly connected to the slot in charge based on the cable system of the contact device 100, which will be described below, and transmit the electrical signal to the cartridge 120 to proceed with the multi-test of the wafer (not illustrated).

The tester 130 is preferably inspection equipment (e.g., Advantest V93000 or Teradyne J750) capable of conducting a multi-test for inspecting whether the wafer (not illustrated) is good or defective.

On the other hand, when the contact device 110 of the present invention is electrically connected to the cartridge 120, a cable system (‘cabling’ in FIG. 2) may be configured to transmit the electrical signal of the tester 130 to the cartridge 120 to inspect whether the wafer (not illustrated) is good or defective through the first ZIF connector 114.

In the exemplary embodiment, the cable system may be a system in which a cable is configured to transmit an electrical signal for inspecting whether the wafer (not illustrated) is good or defective to the cartridge 120 in the slot in which each tester 130 is responsible.

The tester 130 of the exemplary embodiment may proceed a multi-test of a wafer (not illustrated) without interference of a signal due to the other tester 130 through the cable system of the contact device 110.

Specifically, the contact device 110 is configured to transmit an electrical signal, which is a test signal output from each tester 130, to the cartridge 120 in the corresponding slot without interference with an electric signal of another tester 130 through an independent signal path by the cable system, thereby improving test reliability and efficiency during the multi-test of the wafer (not illustrated).

The cable unit 140 may be a support or platform that is disposed on the bottom surface of the chamber 105 and physically seats the cartridge 120 based on contact with the lower portion 124 of the cartridge to induce contact including the contact device 110 in a state in which the cartridge 120 is aligned in position including the contact device 110 in the X, Y, and Z axes.

### Procedure of Electrical Connection

Hereinafter, a procedure of the electrical connection between the first ZIF connector 114 and the second ZIF connector 123 for inspecting whether the wafer (not illustrated) is good and defective will be described in detail with reference to the accompanying drawings.

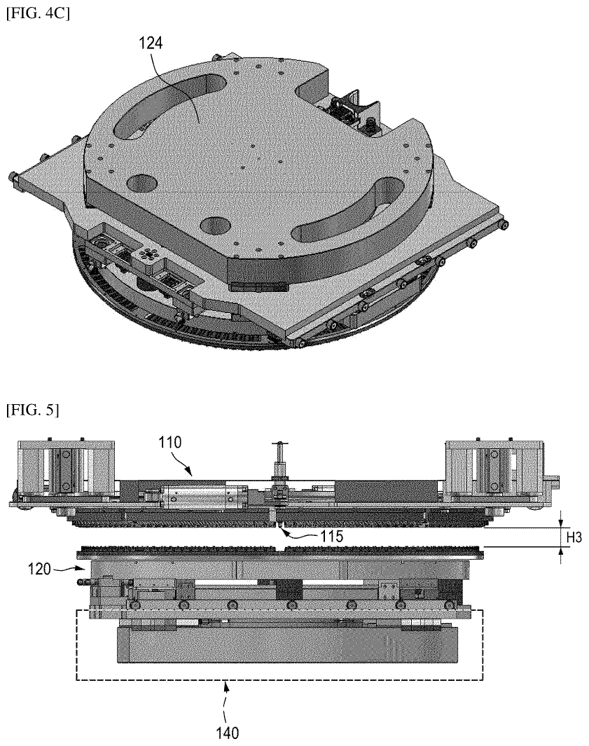

FIGS. 5 to 8 are diagrams illustrating a procedure of an electrical connection between the contact device and the cartridge according to the exemplary embodiment of the present invention.

Referring to FIG. 5, in a state where the contact device 110 is disposed on the ceiling of the chamber 105, the lower surface of the mount 111 from which the first ZIF connector 114 protrudes from the upper portion 121 of the cartridge may be spaced apart by a third gap H3.

Here, the third gap H3 is not limited to the interval between the contact device 110 and the cartridge 120 where the first ZIF connector 114 and the second ZIF connector 123 are not electrically connected, and in the exemplary embodiment, the third interval H3 may be 30 to 50 mm (preferably 40 mm).

Referring to FIG. 6, in the contact device 110, when a pneumatic signal is applied to the pneumatic drive unit 112b provided in the plurality of vertical drive units 112, the shaft 112a in an upwardly moved state may move in the downward direction as an initial position (start position), and the mount 111 may move in the downward direction by the vertical drive unit 112 coupled through the bolt 116.

In this case, in the contact device 110, the first ZIF connector 114 and the second ZIF connector 123 may be electrically connected after contact as the lower surface of the mount 111 is spaced apart from the upper portion 121 of the cartridge by a fourth gap H4.

Here, the fourth gap H4 is preferably less than 0 mm because the first ZIF connector 114 and the second ZIF connector 123 need to be electrically connected after contact.

Furthermore, when the first ZIF connector 114 and the second ZIF connector 123 are electrically connected, the supplied pneumatic pressure may be cut off in the pneumatic drive unit 112b, and as a result, the position of the shaft 112a may be fixed in a downwardly moved state.

In addition, when the first ZIF connector 114 and the second ZIF connector 123 are electrically connected, the plurality of guide pins 115a and 115b may be inserted into the plurality of holes (not illustrated) formed in the cartridge 120, respectively, to limit the degree to which the latch of the first ZIF connector 114 rotates.

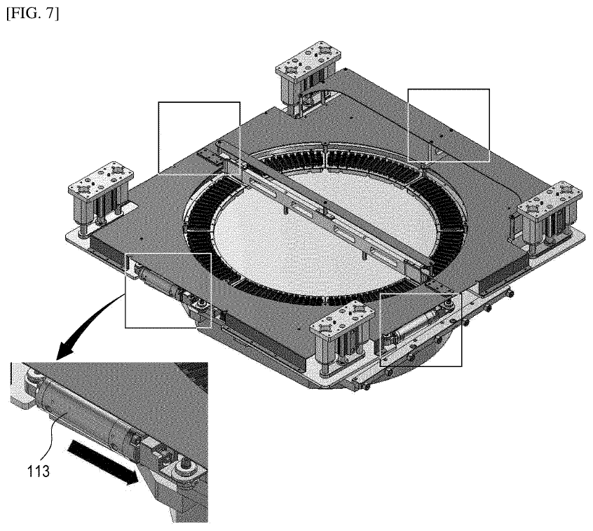

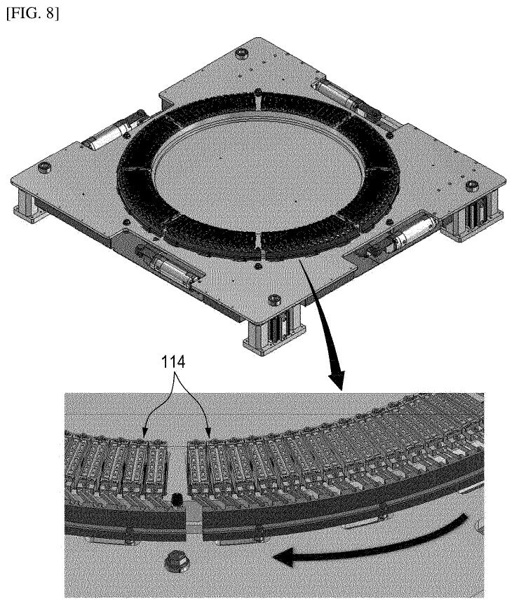

Referring to FIGS. 7 and 8, a pneumatic signal may be applied to the plurality of lock/unlock actuators 113, and the latch of the first ZIF connector 114 in the unlocked state is driven to a locked state according to the applied pneumatic signal to maintain the electrical connection state between the first ZIF connector 114 and the second ZIF connector 123.

Furthermore, when the response signal of the wafer (not illustrated) is transmitted to the tester 130 and thus the test of the wafer (not illustrated) is terminated, the pneumatic pressure supplied to release the electrical connection between the first ZIF connector 114 and the second ZIF connector 123 may be cut off, so that the plurality of lock/unlock actuators 113 may drive the latch of the locked-state first ZIF connector 114 in the unlocked state.

On the other hand, the wafer multi-test system 100 of the present invention is not illustrated in the drawing to proceed with the electrical connection procedure of the exemplary embodiment illustrated in FIGS. 5 to 8, but it is preferable that a pneumatic application means (not illustrated) for applying a pneumatic signal to the pneumatic drive unit 112b and the lock/unlock actuator 113 is configured in the chamber 105, and it is more preferably that a plurality of pneumatic application means (not illustrated) is provided to apply a pneumatic signal to the pneumatic drive unit 112b and the lock/unlock actuator 113 of each slot in the chamber 105.

### Effect of the Present Invention

The wafer multi-test system 100 of the present invention may reduce unnecessary packaging costs by inspecting defective products through a multi-test of a wafer (not illustrated) before semiconductor packaging.

The wafer multi-test system 100 of the present invention may conduct a multi-test of a wafer (not illustrated) without interference of a signal by another tester 130 by disposing the cartridge 120 in which the wafer (not illustrated) is seated in each slot in the chamber 105, and then inspecting, by the test 130 in charge of each slot, only whether the wafer (not illustrated) seated in the cartridge 120 in the slot is good or defective.

The detailed description of the exemplary embodiment of the present invention disclosed as described above has been provided so that those skilled in the art may implement the present invention. Although described above with reference to the exemplary embodiment of the present invention, it will be understood by those skilled in the art that the present invention may be variously modified and changed within a range not departing from the scope of the present invention. For example, those skilled in the art may use the respective configurations described in the above-described exemplary embodiment in a manner of combining each other. Accordingly, the present invention is not intended to be limited to the exemplary embodiment present herein, but is intended to give the broadest range consistent with the principles and novel features disclosed herein.

The present invention may be embodied in other specific forms without departing from the technical spirit and essential features of the present invention. Therefore, the above detailed description should not be construed in all aspects restrictively and should be considered illustrative. The scope of the present invention should be determined by reasonable interpretation of the appended claims, and all changes within the equivalent scope of the present invention are included in the scope of the present invention. The present invention is not intended to be limited to the exemplary embodiment present herein, but to give the broadest range consistent with the principles and novel features disclosed herein. In addition, the exemplary embodiment may be formed by combining the claims that have no explicit citation relationship in the claims, or may be included as a new claim by an amendment after a patent application is filed.

What is claimed is:

1. A wafer multi-test system including a contact device, the wafer multi-test system comprising:
a contact device provided with a mount that is movable in an upward direction or a downward direction, and has a lower surface on which a first ZIF connector electrically connectable to a cartridge in which a wafer is seated when moving in the downward direction is disposed,
wherein the contact device includes a cable system that is configured to transmit an electrical signal of a tester to the cartridge to inspect whether the wafer is good or defective when the contact device is electrically connected to the cartridge.

2. The wafer multi-test system of claim 1, wherein the contact device includes a plurality of vertical drive units arranged at respective corners of the mount to move the mount in the upward direction or the downward direction or fix a position of the mount.

3. The wafer multi-test system of claim 2, wherein the plurality of vertical drive units moves the mount in the upward direction or the downward direction according to an applied pneumatic signal, but fixes the position of the mount when the supplied pneumatic pressure is cut off.

4. The wafer multi-test system of claim 1, wherein in the contact device, the first ZIF connector is disposed in a circular shape in a center of the mount.

5. The wafer multi-test system of claim 4, wherein the first ZIF connector is electrically connected to a second ZIF connector disposed in a circular shape on a circumference of an interface board provided in the cartridge when the mount moves in the downward direction.

6. The wafer multi-test system of claim 4, wherein the contact device includes a plurality of lock/unlock actuators disposed on respective sides of the mount and connected to the first ZIF connector to drive a latch of the first ZIF connector in a locked or unlocked state.

7. The wafer multi-test system of claim 6, wherein the plurality of lock/unlock actuators drives the latch of the first ZIF connector in the locked state according to an applied pneumatic signal to allow the first and second ZIF connectors to be electrically connected when the contact device moves in the downward direction, and
when the supplied pneumatic pressure is cut off after a test of the wafer is completed, the plurality of lock/unlock actuators drives the locked-state latch of the first ZIF connector in the unlocked state to release the electrical connection between the first and second ZIF connectors.

8. The wafer multi-test system of claim 1, wherein the contact device includes a guide pin placed at a position where the first ZIF connector is divided into a plurality of connectors to correct vertical and horizontal position alignment errors of the first ZIF connector when the contact device and the cartridge are electrically connected.

9. The wafer multi-test system of claim 1, wherein the cartridges are provided in plural to be disposed in a plurality of slots formed in a chamber accommodating the contact device, the cartridge, and the tester, respectively, and
the testers are provided in plural to inspect only whether the wafer seated in the cartridge of each slot is good or defective.

10. The wafer multi-test system of claim 9, wherein the cable system allows the electrical signal to be transmitted to the cartridge in the slot in which each tester is charge to proceed multi-testing of the wafers.

11. The wafer multi-test system of claim 10, wherein the contact device is configured to transmit an electrical signal output from each tester to the cartridge in the slot without interference of an electrical signal from another tester through an independent signal path, to improve test reliability and efficiency during the multi-testing of the wafers.
